(19) United States
(12) Patent Application Publication
(10) Pub. No.: US 2013/0328587 A1
(43) Pub. Date: Dec. 12, 2013

(54) LED SOLAR SIMULATOR

(71) Applicant: Spire Corporation, Bedford, MA (US)

(72) Inventors: Kurt J. Linden, Wayland, MA (US); William R. Neal, Bedford, MA (US); Harvey B. Serreze, Pepperell, MA (US)

(73) Assignee: Spire Corporation, Bedford, MA (US)

(21) Appl. No.: 13/896,768

(22) Filed: May 17, 2013

Related U.S. Application Data
(60) Provisional application No. 61/656,281, filed on Jun. 6, 2012.

(51) Int. Cl. G01R 31/26

(52) U.S. Cl. CPC G01R 31/2605
USPC 324/761.01; 29/592.1

(57) ABSTRACT

An LED based solar simulator and method. An emitter plane includes an array of quarter panels below a test plane. Each quarter panel includes multiple close pitch LEDs of different wavelengths in an array, a plurality of LEDs for select wavelengths per quarter panel, and one or more different wavelength LEDs in a plurality of class A wavelength intervals in order to more closely match the solar spectrum.

### RELATED APPLICATIONS

This application claims the benefit of and priority to U.S. Provisional Application Ser. No. 61/656,281 filed Jun. 6, 2012 under 35 U.S.C. §§119, 120, 363, 365, and 37 C.F.R. §1.55 and §1.78 and is incorporated herein by this reference.

### GOVERNMENT RIGHTS

This invention was made, at least in part, with U.S. Government support under DOE Phase I SBIR Grant No. DE-SC0004842, Jun. 19, 2010-Mar. 18, 2011, and DOE Phase II SBIR Grant No. DE-SC0004842, Aug. 15, 2011-Aug. 14, 2013. The Government may have certain rights in the subject invention.

### FIELD OF THE INVENTION

This invention relates to an adjustable spectrum LED solar simulator system and method.

### BACKGROUND OF THE INVENTION

A solar simulator is used to test and/or evaluate solar cells and modules, a module consisting of an assembly of electrically connected cells. The solar cell or module is placed on a test plane glass beneath or above which is a light source and various filters, mirrors, baffles, and the like. The light source is usually a xenon tube.

The goal is to match the solar (sun's) spectrum as close as possible with a class A spectrum defined as a certain irradiance within wavelength intervals between 400-1100 nm.

Recently, researchers have begun exploring LED-based solar simulators. See Kolberg, et al. “Homogeneity And Life Time Performance Of A Tunable Close Match LED Solar Simulator Energy,” Procedia 27 (2012) 306-311 and Swonke and Hoyer, “Concept For A Real AM1.5 Simulator Based On LED-Technology And Survey On Different Types Of Solar Simulators,” 24th European Photovoltaic Solar Energy Conference, 21-25 Sep. 2009, Hamburg, Germany, (3377-3379) both incorporated herein by this reference. See also published Application Serial Nos. 2013/0069687 and 2013/0063174 also incorporated herein by this reference.

### SUMMARY OF THE INVENTION

In some cases, class A solar simulator performance is predicated based on the IEC and ASTM standards, IEC 60904-9 and ASTM E927-10, respectively. For some solar module technologies (e.g., single-junction thin-film approaches and multi junction tandem structures), a solar simulator which exceeds class A performance and more closely matches the solar spectrum is desired. Also, it is desirable to fine tune the simulator output to meet the user's needs and requirements. In most cases, homogeneity, reliability, repeatability, maintainability, cost and scalability are key considerations. Spectral mixing and uniform illumination in the solar cell test plane are also key considerations.

Featured is an LED based solar simulator comprising a test plane for a solar cell or module and an emitter plane comprising an array of quarter panels below the test plane forming at least one panel. Each quarter panel includes multiple LEDs of different wavelengths in an array, a plurality of LEDs for select wavelengths per quarter panel, and one or more different wavelength LEDs in a plurality of class A wavelength intervals. Mirrored sidewalls extend from the emitter plane to the test plane.

Preferably, each class A wavelength interval includes one or more different wavelength LEDs. The pitch of the LEDs is preferably much less than the distance between the emitter plane and the test plane. In one example, the pitch of the LEDs is approximately 0.5 cm and the distance between the emitter plane and the test plane is approximately 10 cm. Also, the simulator uses bare chip LEDs for higher density LEDs per quarter panel, but could also use packaged LEDs, provided that they are small enough. In one version, each quarter panel further includes a light sensor positioned to detect light reflected off the test plane. The light sensor may be a photodiode and a circumferential shield around the photodiode shields the photodiode from direct LED light. Preferably, the simulator LED driver subsystem is responsive to the light sensor and is configured to selectively control LEDs in response. There may be one or more drivers per panel and typically the driver subsystem is connected to a panel in a configuration in which LEDs of different wavelengths can be selectively controlled per quarter panel. For example, the LED driver subsystem may include a controller connected to one or more drivers for each quarter panel and programmed to selectively control LEDs of different wavelengths to minimize the difference between the emitter plane spectrum and a stored solar spectrum.

Also featured is a method of fabricating an LED based solar simulator comprising populating a quarter panel to include multiple LEDs of different wavelengths, joining quarter panels to form a panel, joining panels to form an emitter plane, and forming a test plane spaced from the emitter plane via sidewalls including mirrored surfaces. In one example, each quarter panel includes multiple LEDs of select wavelengths and one or more different wavelength LEDs in a plurality of class A wavelength intervals.

Populating a quarter panel may include using bare chip LEDs or packaged LEDs and choosing a pitch for the LEDs to be much less than the distance between the emitter plane and the test plane.

One method may further include adding a light sensor on each quarter panel positioned to detect light reflected off the test plane and adding an LED driver subsystem to be responsive to the light sensor and configuring the LED driver subsystem to selectively control the LEDs in response. The driver subsystem may be connected to each panel in a configuration in which LEDs of different wavelengths can be selectively controlled at the quarter panel level.

Also featured is a method of simulating the solar spectrum. An LED driver subsystem is connected to individual panels of an image plane each including a plurality of LEDs of different wavelengths—a number of which wavelengths include multiple LEDs. The LED driver subsystem is used to control the power applied to individual LEDs and/or strings of LEDs of the same wavelength. The output at the image plane is monitored and the LED driver subsystem is adjusted in response.

The subject invention, however, in other embodiments, need not achieve all these objectives and the claims hereof should not be limited to structures or methods capable of achieving these objectives.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic three dimensional view of an example of a solar simulator in accordance with the invention;

FIG. 2 is a graph showing the solar spectrum and also the output of the simulator of FIG. 1;

FIG. 3 is a schematic top view of a quarter panel of the solar simulator shown in FIG. 1;

FIG. 4 is a wiring diagram of the quarter panel of FIG. 3;

FIG. 5 is a schematic top view showing four quarter panels assembled as a single simulator panel;

FIG. 6A is a schematic top view of a solar simulator panel combined with a mirrored wall;

FIG. 6B is a schematic bottom view of the assembly of FIG. 6A;

FIG. 7 is a schematic view showing a solar simulator panel assembled with a cable junction board;

FIG. 8 is an exploded schematic view showing a solar simulator panel assembled with a cable junction board, one or more LED driver boards, a central processing board, and the like for a full solar cell simulator system in accordance with examples of the invention;

FIG. 9 is a schematic block diagram showing how individual LEDs are controlled in accordance with examples of the invention;

FIGS. 10 and 11 show top plan and side cross sectional views, respectively, of representative LEDs that may be used in this invention;

FIG. 12 is a block diagram of a micro-processor based controller for a single series LED string of common color range according to one embodiment of the invention;

FIG. 13 is a schematic diagram of a DC charging bus for panel capacitor banks;

FIG. 14 is a schematic diagram of a DC-DC buck converter for driving series LED strings of common color range according to the invention;

FIG. 15 is a schematic block diagram showing an arrangement of series strings of common color range which extend through the lowest order assemblies, e.g. quarter panel sub-block LEDs and their next higher order intermediate assemblies, e.g. panels; four of which make up the next higher intermediate assembly, e.g. a multi-panel;

FIG. 16 is a diagram showing one embodiment of the simulator method run mode according to this invention; and

FIG. 17 is a diagram showing one embodiment of the simulator method calibration mode according to this invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

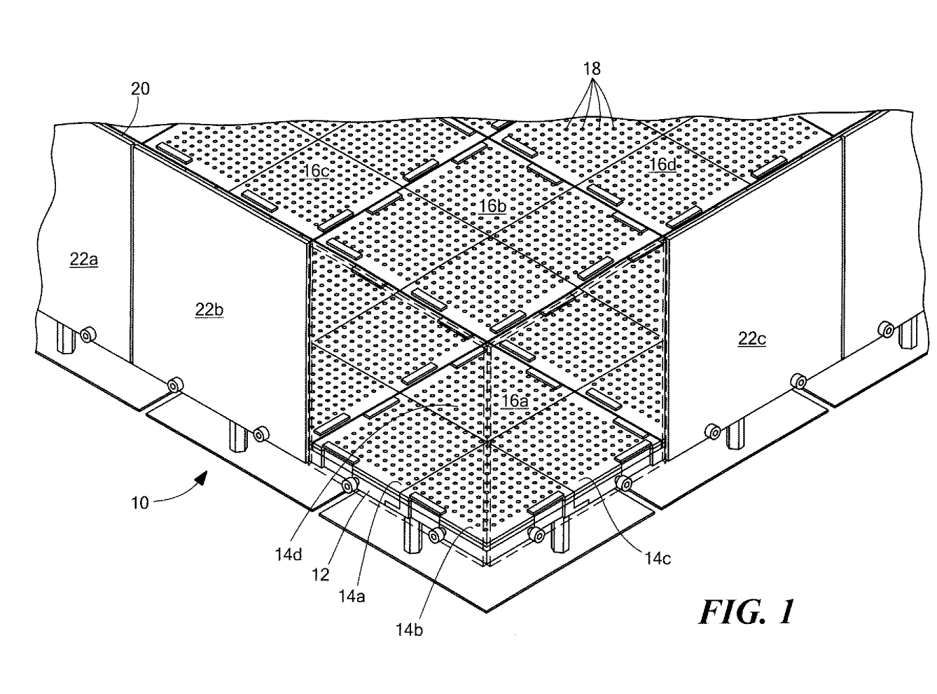

FIG. 1 shows solar simulator 10 in one inventive example with emitter plane 12 comprising an array of quarter panels 14a, 14b, 14c, 14d, and the like. Each quarter panel is typically identical in construction and layout and thus each panel 16a-16d is typically identical in construction and layout advantageously improving scalability, manufacturability, repairability, and reliability.

Here, each quarter panel 14 includes an array of (e.g., 100) LEDS 18 populating a circuit board with the necessary interconnects, leads, bond pads, cabling, and the like. In the preferred embodiment, bare LED chips are used because they can easily be mounted in close proximity on a printed circuit board as opposed to packaged LEDs. In each quarter panel, there are multiple LEDs of different wavelengths. In one example, there are twenty-three LED types as follows:

| Wavelengths (nm) | Power (mW/cm²) | Number per Quarter Panel |
|---|---|---|
| 362 | 0.9207 | 1 |
| 382 | 2.0255 | 1 |
| 403 | 3.7051 | 1 |
| 418 | 3.8893 | 1 |
| 456 | 3.4931 | 1 |
| 474 | 2.6896 | 1 |
| 499 | 1.8972 | 1 |
| 523 | 1.1662 | 1 |
| 589 | 1.1830 | 1 |
| 621 | 2.9741 | 1 |
| 650 | 3.1192 | 1 |
| 675 | 2.8179 | 6 |
| 700 | 9.0508 | 14 |
| 740 | 5.4405 | 7 |
| 760 | 2.3659 | 3 |
| 780 | 2.1260 | 3 |
| 830 | 3.2141 | 4 |
| 870 | 5.1503 | 7 |
| 925 | 2.8737 | 8 |
| 970 | 0.6696 | 2 |
| 1020 | 4.2464 | 11 |
| 1050 | 4.9997 | 18 |
| White | 6.9806 | 6 |

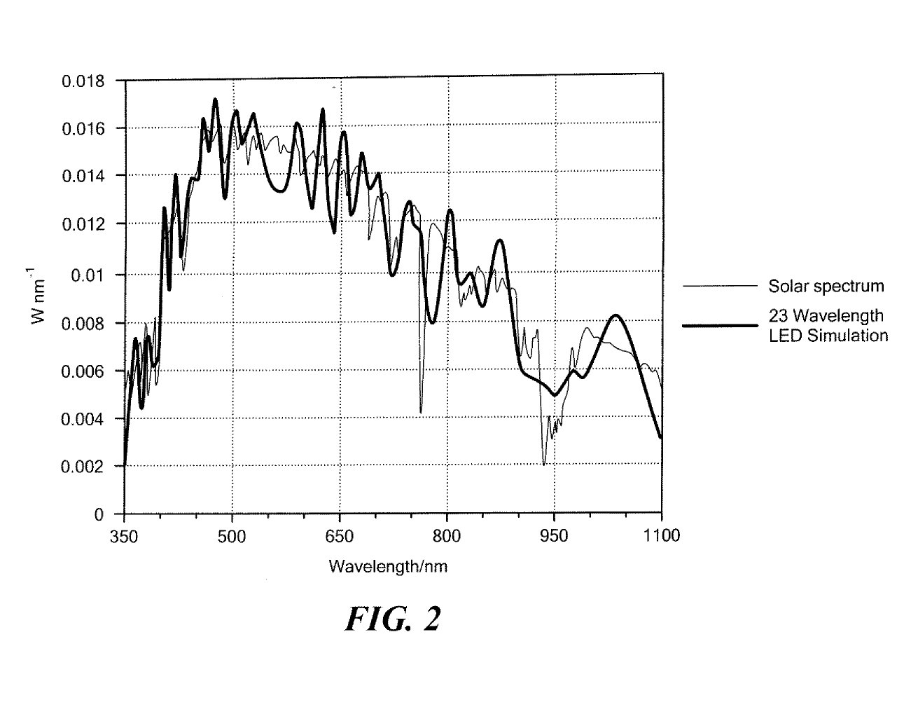

In the class A spectrum, the defined wavelength intervals are 400-500, 500-600, 600-700, 700-800, 800-900, and 900-1100 nm. Thus, in each class A interval, there are, in this preferred embodiment, two to four or more LEDs of different wavelengths resulting in a simulator which exceeds class A performance requirements and which more closely matches the solar spectrum as shown in FIG. 2. Spectral mixing is enhanced and there is uniform illumination in the solar cell test plane. LEDs in the IR spectral range are also provided.

Indeed, the simulator system of this invention can automatically tune itself to reliably output a spectrum at test plane 20, FIG. 1 closely matching the actual solar spectrum. Typically, side mirrors 22a, 22b, 22c and the like for a portion of the side walls of the simulator extend from the emitter plane 12 upward to test plane 20.

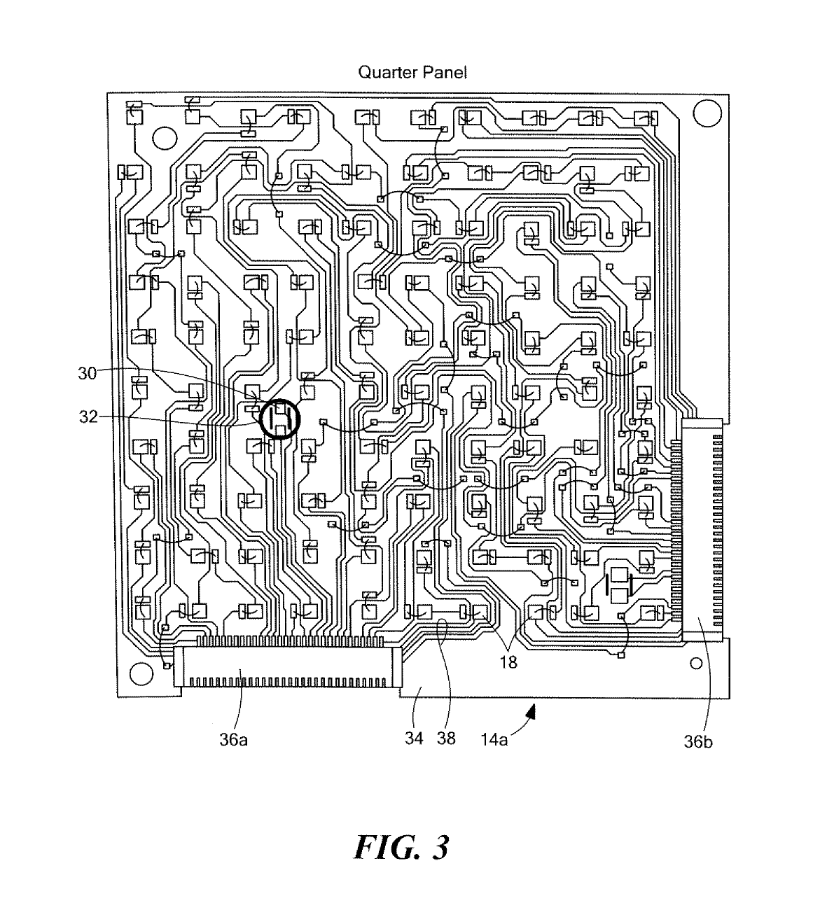

In one example, each quarter panel 14a, FIG. 3 has 100 LEDs 18 with a pitch of 0.5 cm between individual LED centers. By designing the test plane to be separated from the emitter plane defined by the LEDs to be much greater than the pitch between the individual LEDs, the homogeneity of the radiation at the test plane is improved. Spectral mixing is improved and there is uniform illumination at the solar cell test plane. In one example, the test plane is 10 cm from the emitter plane.

Each quarter panel 14a may also include a light sensor such as one or more photodiode chips 30 surrounded by circumferential shield 32 (extending, for example a few mm upwards) from printed circuit board 34.

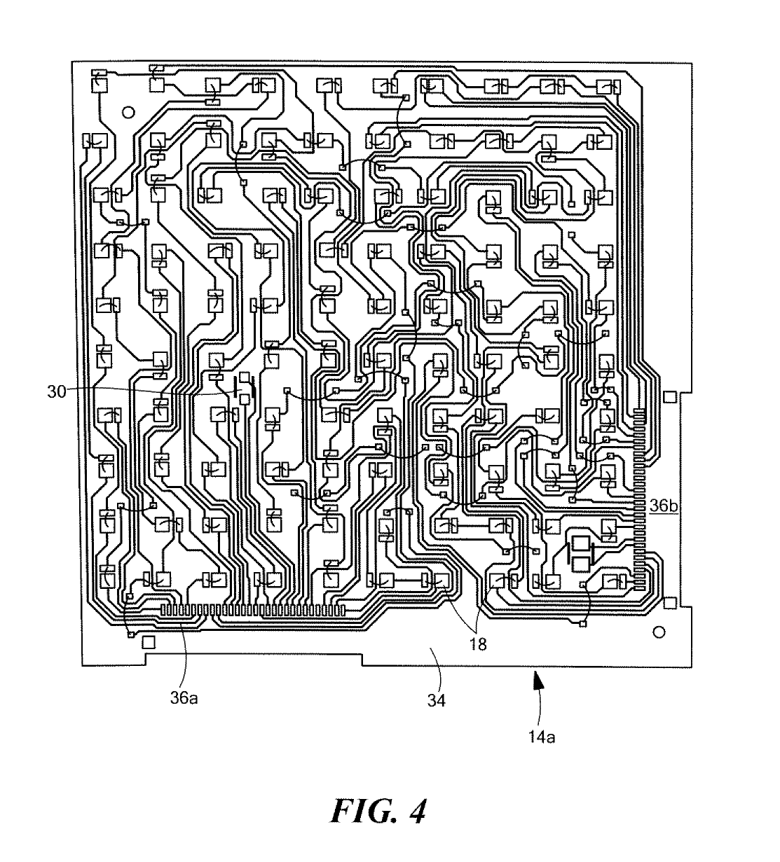

Printed circuit board 34 also includes ribbon cable connectors 36a and 36b which include conductors leading to traces 38 which ultimately lead to the individual LEDs (or strings of LEDs). FIG. 4 shows the traces of printed circuit board 34 more clearly and the different wavelength LEDs in a 10 by 10 array. In other examples, packaged LEDs can be used.

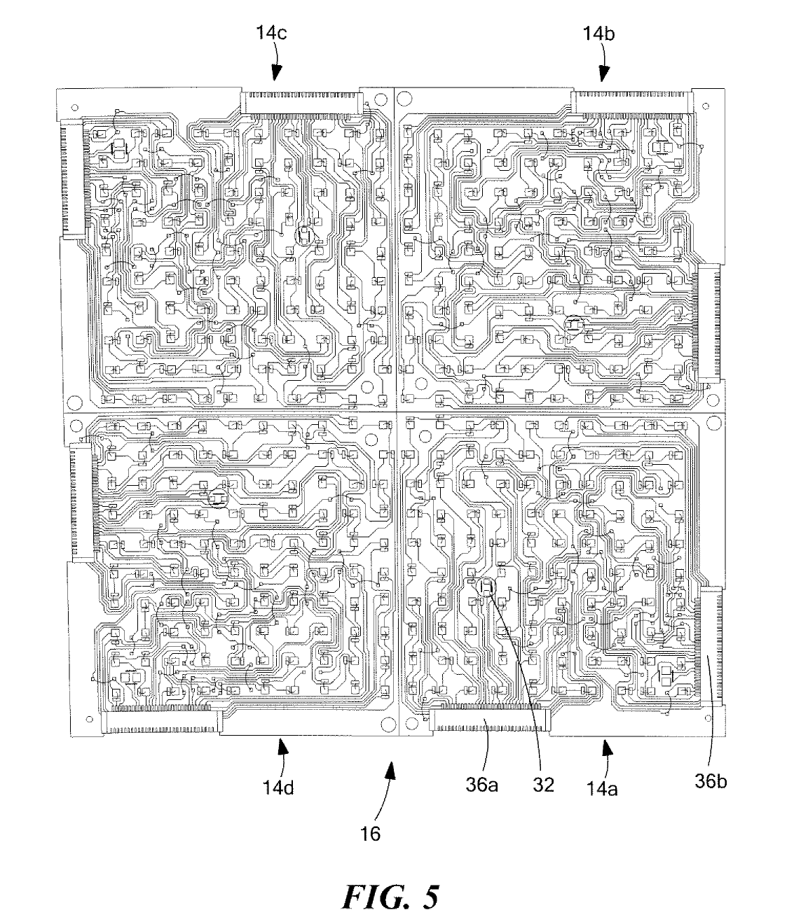

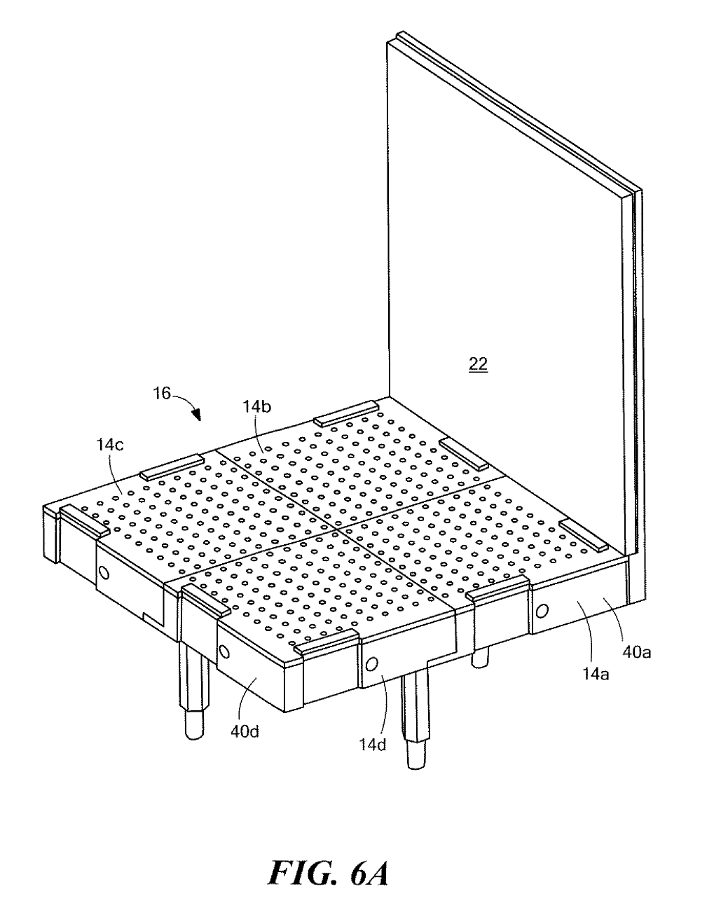

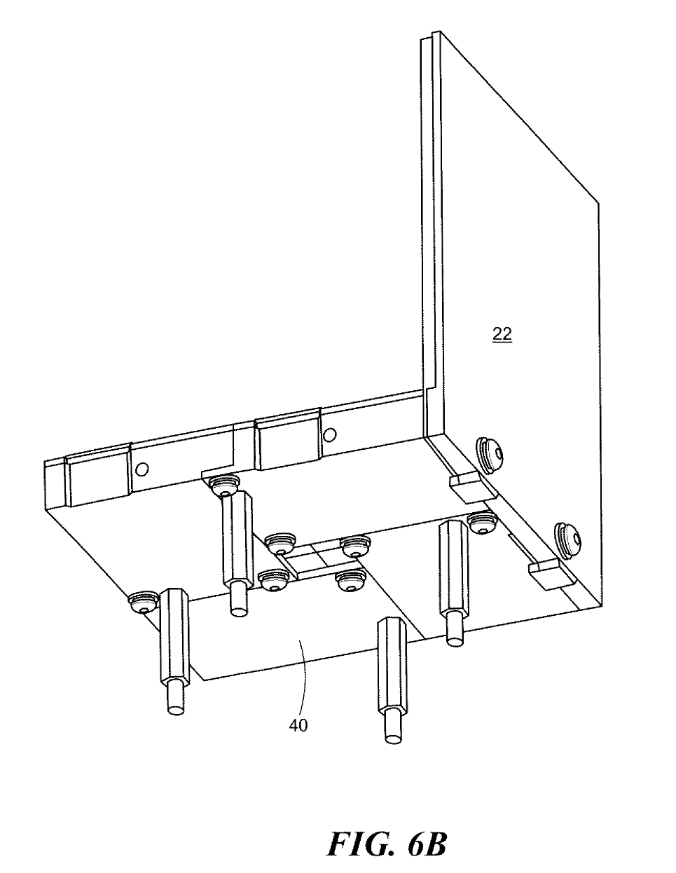

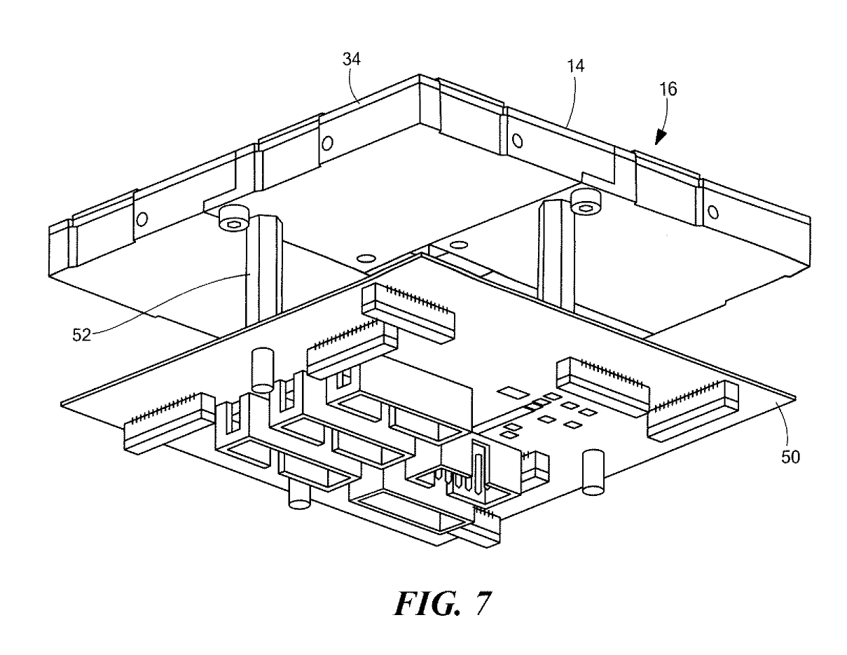

FIG. 5 shows four quarter panels 14a, 14b, 14c, and 14d forming panel 16. In one preferred embodiment, each quarter panel 14, FIG. 6A-6B includes a printed circuit board with bare chip LEDs mounted to a fixture 40 four of which are assembled together to form a panel 16. Then, each panel is mounted to cable junction board 50, FIG. 7 with flex cable routing to the connectors of each quarter panel. Standoffs 52 connect panel 16 to cable junction board 50.

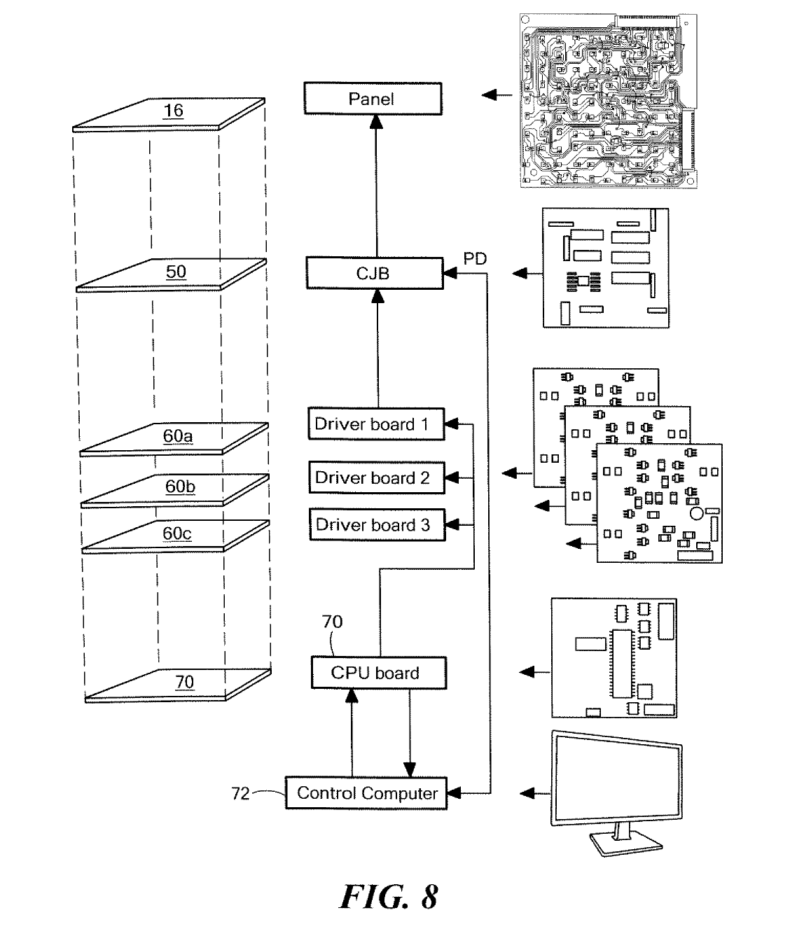

Each panel further includes electric driver boards 60a, 60b, 60c FIG. 8 electrically connected to cable junction board 50 and controlled by CPU board 70 (including a processor, microcontroller, field programmable gate array, application specific integrated circuit, or the like) itself preferably programmed and/or controlled by control computer 72.

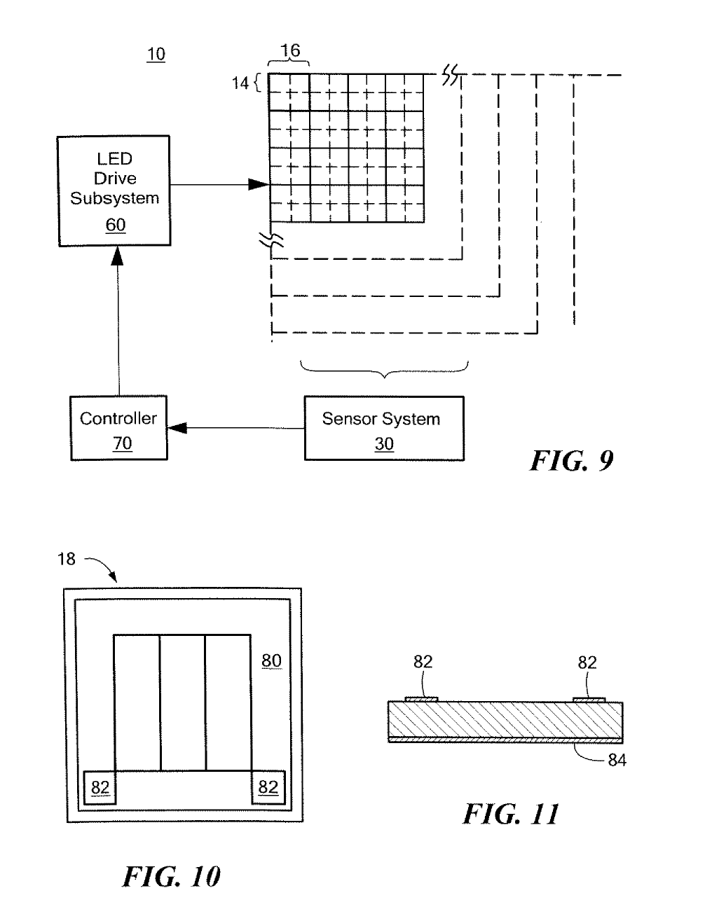

In this way, as shown in FIG. 9, the output of a sensor system (e.g., the photodiode on each quarter panel responsive to light reflected off the underside of the glass test plane) can be used by a controller subsystem to control the LED drive subsystem 60 to turn strings or even individual LEDs of a quarter panel on and off, to increase or decrease their output, and the like. In this way, solar spectrum matching is achieved and/or the user can input a desired spectrum (via computer 72, FIG. 8) and the solar simulator system automatically matches or approximates the user's desired spectrum. Different wavelength LEDs at the quarter panel level can be selectively controlled. There could even be one or more driver boards dedicated to each quarter panel.

The result is a uniform illumination at the solar cell test plane and enhanced spectral mixing. Reliability, repeatability, maintenance, and scalability are addressed.

In one example, an LED drive subsystem 60 provides power to the LED chips. A sensor system senses the output of the LEDs. Controller 70, which may include a microprocessor such as a Microchip Corp., PIC family of microcontrollers programmed with, among other things, LabVIEW software which responds to the sensor system to compare the color spectrum of the output of the LEDs to a desired solar spectrum and enables the LED driver subsystem 60 to adjust the power to the LEDs to more closely match a standard or desired solar spectrum. Solar spectrum standards have been set by two principal organizations, IEC and ASTM International. A Class A spectrum is essentially defined as one that falls within ±25% of the Air Mass 1.5 Global (AM1.5G) spectrum. In one embodiment of this invention the LEDs of e.g. a quarter panel, are connected in series strings or chains of common color range. LED driver system 60 provides power separately to each of those series strings of common color range. The common color ranges for example could be red, orange, yellow, green, blue, violet. In this way, controller 70, selectively adjusts the power to the series strings of common color range in order to balance or more closely match the LED output spectrum of the system 40 with the desired solar spectrum. A typical LED chip 18, FIG. 10 may be an EZBright LED having a nominally 980×980 μm² area of dielectric passivation layer 80 and gold bond pads 82 with a backside metallization anode 84, FIG. 11.

The light emanating from the LEDs with different wavelength is homogenized and the intensity of the light is uniform as it impinges on the solar cell or solar panel to be tested.

In accordance with one embodiment the LED driver system includes a capacitive circuit for periodically discharging power to the LEDs and recharging between those power discharges. Since the solar spectral density in the wave length interval of 400-1100 nm is about 760 W/m² or equivalently 76 mW/cm², the 20 cm×20 cm panel 16, must produce close to 30 watts of optical power. Using a conservative average radiation production efficiency of η approximately equal to 10%, the electrical power to all the LEDs in the panel during a 100 ms flash would be about 300 W. Each 100 ms flash of the simulator would then deliver an energy of some 30 Joules to the LEDs. For power conversion efficiency this energy could come from a panel-mounted capacitor, initially charged to 400 V and discharged in the 100 ms interval to 200 V; the required value C of the capacitor is then found from:

$$\begin{matrix}Δ {E}_{LED} = 30 J = \frac{C}{2} {400}^{2} - \frac{C}{2} {200}^{2} = 6 \times {10}^{4} C so that & ( 1 ) \\ C = \frac{30}{6 \times {10}^{4}} = 500 μ F & ( 2 )\end{matrix}$$

If this capacitor is discharged from 400 V to 200 V in 100 ms at a constant current I_{LED}, then

$$\begin{matrix}Δ Q = {I}_{LED} Δ t = C Δ V so that & ( 3 ) \\ {I}_{LED} = 500 \times {10}^{- 6} \frac{200}{0.1} = 1 A & ( 4 )\end{matrix}$$

To restore to the capacitor the same charge as was discharged in 100 ms, but in the 10 s between flashes, then a current of only one hundredth of the discharge current or 10 mA is required. For the 400 V main supply charging the capacitor banks of the 50 panels constituting a 1 m×2 m solar simulator, a current capacity of about 500 mA is required: i.e., a 200 W supply.

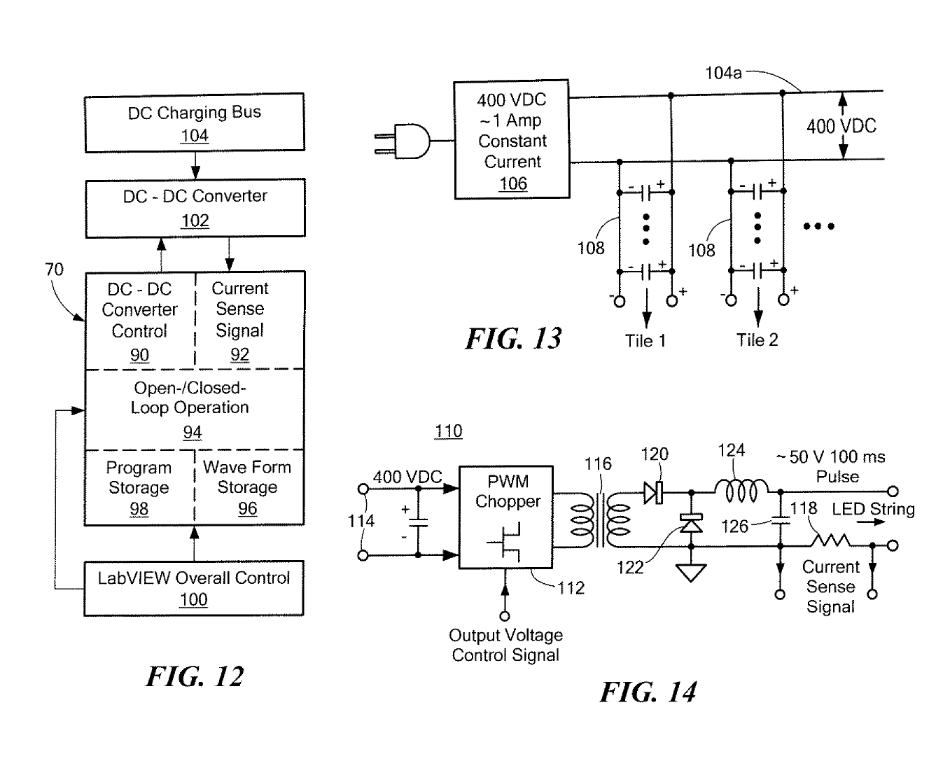

One embodiment of a microprocessor-based controller 70, FIG. 12 is configured to provide DC to DC converter control 90 as well as current sensing 92. It is capable of both open and closed loop operation 94 and provides both waveform storage 96 and program storage 98 and may employ LabVIEW overall control software 100 as well as other software. It operates in conjunction with DC to DC converter 102 and DC charging bus 104. A more detailed view of the DC charging bus 104a, FIG. 13, shows a 400 V DC 1 amp current supply, 106 which provides a capacitive powered output 108 for each panel. A general schematic of a typical DC-DC buck converter 110, FIG. 14 includes a pulse width modulated chopper 112 which receives the 400 V DC at input 114 and employs an isolation transformer 116 which permits individual local grounding of the panels. The fraction of the input 400 V appearing across the LED string is determined by pulse-width modulating (PWM) the chopper function via an external control signal. For purposes of feedback control, the output LED string current may be sampled by a current sensor resistor 118. Converter 110 also includes rectifying 120 and free-wheeling 122 diodes, inductor 124, and filter capacitor 126.

In one embodiment the series strings of common color range LEDs are driven in groups of quarter panels. A panel LED driver structure may include three or more DC-DC converters and control electronics printed circuit boards.

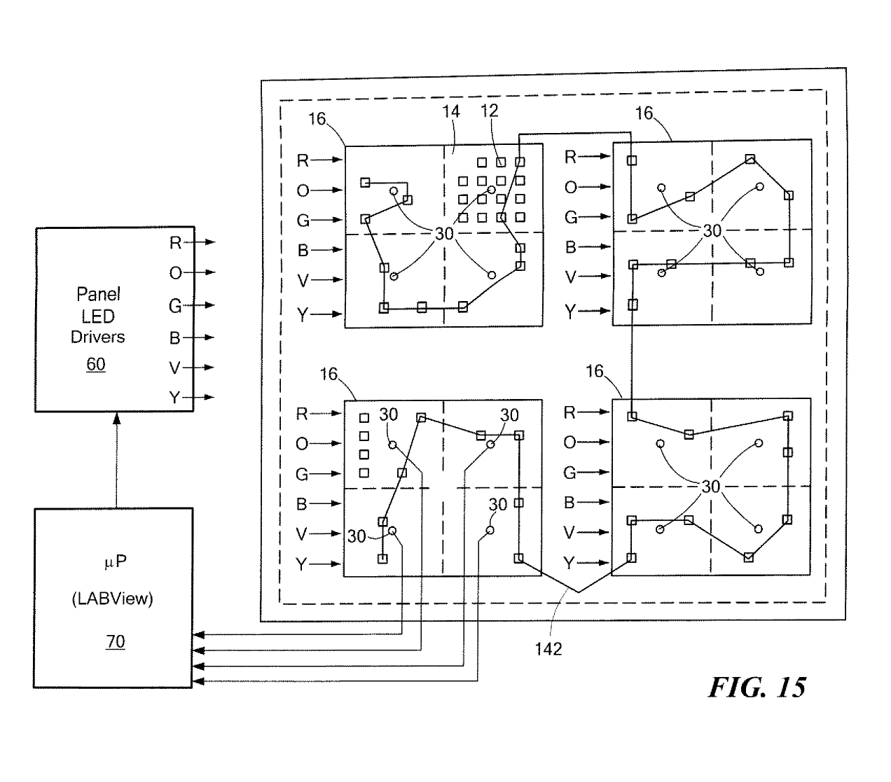

There is shown in FIG. 15 a schematic block diagram of an arrangement of series strings of common color ranges which extend through the lowest order assemblies (quarter panels 14), and the next higher order intermediate assemblies (panels 16) which make up the multi-panel simulator. Panel LED driver 60 provides power to the different series strings of common color range, red, R; orange, O; yellow, Y, green, G; blue, B; violet, V, and the like. Power is provided separately to the strings of LEDs in each quarter panel. To do this, LEDs in the same color range may be connected together in a series string as indicated by the series string 142 which interconnects red LEDs in each quarter panel 14. A similar string may exist for orange, O, green, G, blue B, yellow Y and violet, V so that the LEDs of each different color range can be separately addressed for power adjustment. Each quarter panel also includes a photosensor device 30 which provides input to controller microprocessor 70.

The system can operate in a run mode and in a calibration mode. In the run mode, the microprocessor controller responds to the photo sensor devices and compares the electrical signal spectrum to a predetermined norm to determine the “LED dark/light performance”. In a calibration mode, the microprocessor controller enables the LED drivers to provide distinctively coded (e.g. a different electrical modulation frequency for each color) power to each of the series strings of common color range and then responds to the output from the sensor system including the photo sensors to determine the power of each common color range and compares the power of each of the common color ranges to the power of those colors for a desired solar spectrum. The controller then operates the LED drivers to increase or decrease the power provided on the lines R, O, Y, G, B, V, and the like as necessary.

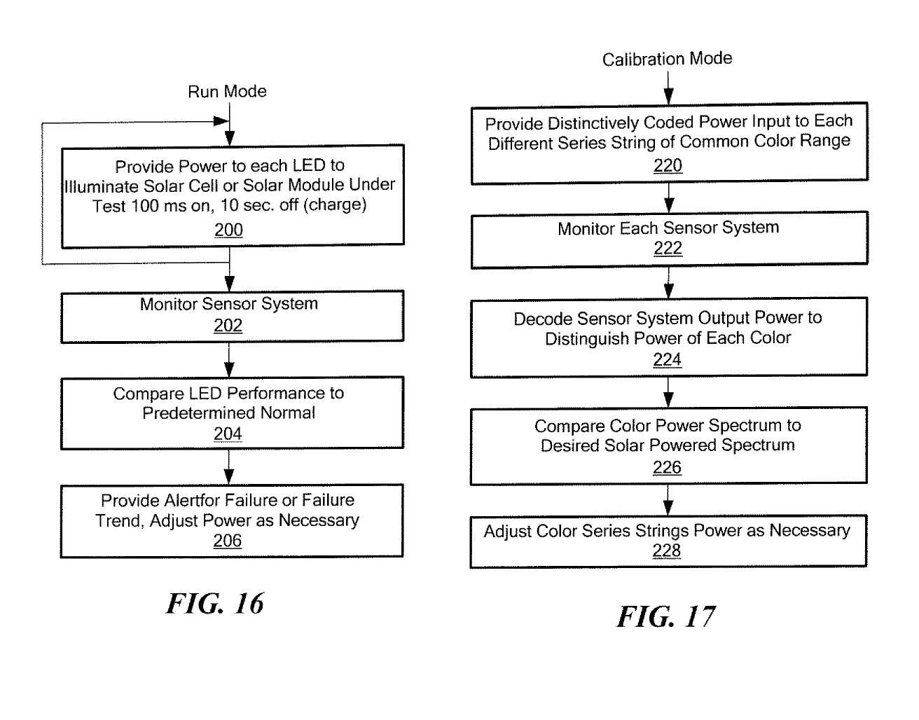

In the run mode as indicated in FIG. 16 power is provided to the LEDs to illuminate the solar cell or solar module under test 200, typically 100 ms of discharge, 10 seconds of charge. The output of the solar module at this time is then examined to determine the characteristics and quality of the solar module. At the same time, the system according to this invention may monitor its sensor system 202 and compare the LED performance to a predetermined norm 204, such as a “dark/light standard”. If that standard is not met 206 an alert may be provided of a failure or failure trend and the power may be adjusted as necessary or quarter panels of LEDs may be swapped out.

In a calibration mode, the LED drivers under control of the microprocessor controller provide distinctively coded power input to each different series string of color range 220, FIG. 17. The coding may be any suitable coding technique: frequency, pulse code modulation, or any other coding approach. The sensor system including the implicated photosensor devices are monitored 222, and the sensor system output power is decoded to distinguish the power of each of the different color ranges 224. The color power spectrum so obtained is compared to a desired solar power spectrum 226 and in response the power of the color series strings is selectively adjusted as necessary 228.

Alternatively, LED calibration may be implemented in such a manner that 1) the relative intensities of the R, O, Y, G, B and V serial strings of LEDs in e.g. a quarter panel 14, are adjusted to the desired solar spectral intensity ratios with the aid of a spectrometer preferably programmed to integrate over the six ASTM-defined wavelength intervals and return the relative intensity values; and 2) the LED-string current drive waveforms that produce constant light output intensity are recorded and saved in the waveform storage area 96 for possible use in the event that some LED light outputs might vary too much with constant current drive. Since a single photodiode sensor 28 is used to monitor all the colors within any given sub-block 10, the individual color LED strings will accordingly have to be sequentially selected for excitation. In this calibration mode the system operates in an optically closed-loop fashion: the LED light output of the selected color is monitored by the photodiode sensor 30 and the signal thus obtained is used to control 90 the LED serial string current driver 60 so as to provide constant light intensity. In the process the LED string current drive waveform is recorded and saved.

In the run mode as indicated in FIG. 16 power is provided to the LEDs to illuminate the solar cell or solar module under test 200, typically for 100 ms of discharge and 10 seconds of recharge. The current vs. voltage output of the solar panel at the time is then measured to determine the solar panel's characteristics and quality. At the same time the system according to this invention may monitor its sensor system 202 and compare the aggregate LED intensity performance to a predetermined norm 204, such as a desired fraction of the intensity of one sun. If that standard is not met an alert may be provided of an actual failure or of a failure trend, so that the power may be adjusted as necessary or LEDs or sub-blocks of LEDs may be replaced. In the run mode the system no longer operates as an optically closed loop; instead the LED-string current sense signals 118 are now used to slave the LED serial string current drivers 102 to predetermined either constant values or stored waveforms as determined by the desired degree of spectral conformity with the ASTM standard. The totalized signals of the photodiode sensors 30 of e.g. a quarter panel, can be used to monitor the total light intensity produced by the quarter panel.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. An LED based solar simulator comprising:
a test plane for a solar cell or module to be tested;
an emitter plane comprising an array of quarter panels below the test plane fanning at least one panel, each quarter panel including:
multiple LEDs of different wavelengths in an array,
a plurality of LEDs for select wavelengths per quarter panel, and
two or more different wavelength LEDs in a plurality of class A wavelength intervals; and
mirrored sidewalls running from the emitter plane to the test plane.

2. The simulator of claim 1 in which each class A wavelength interval includes one or more different wavelength LEDs.

3. The simulator of claim 1 in which the pitch of the LEDs is much less than the distance between the emitter plane and the test plane.

4. The simulator of claim 3 in which the pitch of the LEDs is approximately 0.5 cm and the distance between the emitter plane and the test plane is approximately 10 cm.

5. The simulator of claim 1 in which the LEDs are bare chip LEDs or packaged LEDs.

6. The simulator of claim 1 in which each quarter panel further includes a light sensor positioned to detect light reflected off the test plane.

7. The simulator of claim 6 in which the light sensor is a photodiode.

8. The simulator of claim 7 further including a circumferential shield around the photodiode.

9. The simulator of claim 6 further including an LED driver subsystem responsive to said light sensor and configured to selectively control LEDs in response.

10. The simulator of claim 9 in which the LED drive subsystem includes one or more drivers per panel.

11. The simulator of claim 10 in which said driver subsystem is connected to said panel in a configuration in which LEDs of different wavelengths can be selectively controlled per quarter panel.

12. The simulator of claim 10 in which said LED driver subsystem includes a controller connected to said one or more drivers for each quarter panel and programmed to selectively control LEDs of different wavelengths to minimize the difference between the emitter plane spectrum and a stored solar spectrum.

13. A method of fabricating an LED based solar simulator comprising:
populating a quarter panel to include multiple LEDs of different wavelengths;
joining quarter panels to form a panel;
joining panels to form an emitter plane; and
forming a test plane spaced from the emitter plane via sidewalls including mirrored surfaces.

14. The method of claim 13 in which each quarter panel includes multiple LEDs of select wavelengths.

15. The method of claim 14 in which each quarter panel includes one or more different wavelength LEDs in a plurality of class A wavelength intervals.

16. The method of claim 13 in which populating a quarter panel includes using bare LED chips.

17. The method of claim 13 in which populating a quarter panel includes choosing a pitch for the LEDs to be much less than the distance between the emitter plane and the test plane.

18. The method of claim 17 in which the pitch of the LEDs is approximately 0.5 cm and the distance between the emitter plane and the test plane is approximately 10 cm.

19. The method of claim 13 further including adding a light sensor on each quarter panel positioned to detect light reflected off the test plane.

20. The method of claim 19 further including adding an LED driver subsystem to be responsive to said light sensor and configuring said LED driver subsystem to selectively control the LEDs in response.

21. The method of claim 20 further including connecting said driver subsystem to said panel in a configuration in which LEDs of different wavelengths can be selectively controlled per quarter panel.

22. A method of simulating the solar spectrum comprising:
connecting an LED driver subsystem to individual quarter panels of an image plane including numerous said quarter panels each including a plurality of LEDs of different wavelengths a number of which include multiple LEDs;
using the LED driver subsystem to control the power applied to individual LEDs and/or strings of LEDs of the same wavelength;
monitoring the output at the image plane; and
adjusting the LED driver subsystem in response.

23. The method of claim 22 in which each quarter panel has one or more different wavelength LEDs in a plurality of class A wavelength intervals.
